(19) United States
(12) Patent Application Publication
(10) Pub. No.: US 2026/0362927 A1
(43) Pub. Date: Nov. 12, 2026

(54) PIXEL ARRANGEMENT STRUCTURE, MASK ASSEMBLY AND DISPLAY PANEL

(71) Applicant: Wuhan Tianma Microelectronics Co., Ltd., Wuhan (CN)

(72) Inventor: Xinya LI, Wuhan (CN)

(73) Assignee: Wuhan Tianma Microelectronics Co., Ltd., Wuhan (CN)

(21) Appl. No.: 19/243,618

(22) Filed: Jun. 19, 2025

(30) Foreign Application Priority Data
Mar. 6, 2025 (CN) 202510264780.9

(51) Int. Cl. H10K 59/35; H10K 71/16

(52) U.S. Cl. CPC H10K 59/353; H10K 71/166

(57) ABSTRACT

The present application discloses a pixel arrangement structure, a mask assembly and a display panel, wherein the pixel arrangement structure comprises a plurality of pixel repeating units; along a first direction, a first pixel group and a second pixel group are arranged adjacently, and the first pixel group and the second pixel group are arranged in mirror symmetry in the second direction; along a second direction, a third pixel group and the first pixel group are arranged adjacently, a fourth pixel group and the second pixel group are arranged adjacently, the third pixel group and the first pixel group are arranged in mirror symmetry in the first direction, and the fourth pixel group and the second pixel group are arranged in mirror symmetry in the first direction.

### CROSS-REFERENCE TO RELATED APPLICATIONS

This application claims priority to Chinese Patent Application No. 202510264780.9, titled “PIXEL ARRANGEMENT STRUCTURE, MASK ASSEMBLY AND DISPLAY PANEL” and filed on Mar. 6, 2025, which is hereby incorporated by reference in its entirety.

### TECHNICAL FIELD

The present application belongs to the technical field of electronic products, and in particular relates to a pixel arrangement structure, a mask assembly and a display panel.

### BACKGROUND

In the display industry, as people's requirements for display effects gradually increase, the display performance of OLED (Organic Light Emitting Diode) will continue to improve; resolution and aperture ratio are two important indicators of device performance.

Due to the limitation of the arrangement form of the existing pixel arrangement structure, the aperture ratio requirements cannot be met.

Therefore, a new pixel arrangement structure, a mask assembly and a display panel are urgently needed.

### SUMMARY

The embodiments of the present application provide a pixel arrangement structure, a mask assembly and a display panel, so as to improve the light emission effect of the pixel arrangement structure when applied to the display panel.

On one hand, the embodiments of the present application provide a pixel arrangement structure, including a plurality of pixel repeating units, the pixel repeating units are repeatedly arranged along a first direction and a second direction, the first direction and the second direction intersect with each other; the pixel repeating unit includes a first pixel group, a second pixel group, a third pixel group and a fourth pixel group, along the first direction, the first pixel group and the second pixel group are arranged adjacently, and the first pixel group and the second pixel group are arranged in mirror symmetry in the second direction, along the second direction, the third pixel group and the first pixel group are arranged adjacently, the fourth pixel group and the second pixel group are arranged adjacently, the third pixel group and the first pixel group are arranged in mirror symmetry in the first direction, and the fourth pixel group and the second pixel group are arranged in mirror symmetry in the first direction; the first pixel group includes a first sub-pixel, a second sub-pixel and a third sub-pixel; in the pixel repeating unit, the four third sub-pixels corresponding to the first pixel group, the second pixel group, the third pixel group and the fourth pixel group are arranged adjacently; along the first direction, the four second sub-pixels included in the two adjacent pixel repeating units are arranged adjacently.

Another aspect of the embodiments of the present application provide a mask assembly for manufacturing the pixel arrangement structure in any one of the above embodiments, the mask assembly includes: a first sub-pixel mask having a first sub-pixel opening, the first sub-pixel opening is configured to form the two adjacent first sub-pixels in the two adjacent pixel repeating units along the second direction; a second sub-pixel mask having a second sub-pixel opening, the second sub-pixel opening is configured to form the four second sub-pixels included in the two adjacent pixel repeating units along the first direction; a third sub-pixel mask having a third sub-pixel opening, the third sub-pixel opening is configured to form the four adjacent third sub-pixels in the pixel repeating unit.

Another aspect of the embodiments of the present application provide a display panel, including the pixel arrangement structure in any one of the above embodiments.

### BRIEF DESCRIPTION OF THE DRAWINGS

In order to more clearly illustrate the technical solution of the embodiments of the present application, the drawings required for use in the embodiments of the present application will be introduced briefly below, apparently, the drawings described below are only some embodiments of the present application. For those skilled in the art, other drawings can be also obtained based on these drawings without creative work.

FIG. 1 is a schematic diagram of a pixel arrangement structure provided by an embodiment of the present application;

FIG. 2 is a schematic diagram of a pixel repeating unit provided by an embodiment of the present application;

FIG. 3 is a schematic diagram of a first pixel group provided by an embodiment of the present application;

FIG. 4 is a schematic diagram of a second pixel group provided by an embodiment of the present application;

FIG. 5 is a schematic diagram of a third pixel group provided by an embodiment of the present application;

FIG. 6 is a schematic diagram of a fourth pixel group provided by an embodiment of the present application;

FIG. 7 is a schematic diagram of a first pixel group provided by another embodiment of the present application;

FIG. 8 is a schematic diagram of a first pixel group provided by another embodiment of the present application;

FIG. 9 is a schematic diagram of a pixel arrangement structure provided by another embodiment of the present application;

FIG. 10 is a schematic diagram of a second pixel group provided by another embodiment of the present application;

FIG. 11 is a schematic diagram of a third pixel group provided by another embodiment of the present application;

FIG. 12 is a schematic diagram of a fourth pixel group provided by another embodiment of the present application;

FIG. 13 is a schematic diagram of a first sub-pixel mask provided by an embodiment of the present application;

FIG. 14 is a schematic diagram of a second sub-pixel mask provided by an embodiment of the present application;

FIG. 15 is a schematic diagram of a third sub-pixel mask provided by an embodiment of the present application;

FIG. 16 is a schematic diagram of a second sub-pixel opening provided by an embodiment of the present application;

FIG. 17 is a schematic diagram of a first sub-pixel mask provided by another embodiment of the present application;

FIG. 18 is a schematic diagram of a second sub-pixel mask provided by another embodiment of the present application;

FIG. 19 is a schematic diagram of a third sub-pixel mask provided by another embodiment of the present application; and

FIG. 20 is a schematic diagram of a second sub-pixel opening provided by another embodiment of the present application.

### DETAILED DESCRIPTION

The features and exemplary embodiments of various aspects of the present application will be described in detail below. In the following detailed description, many specific details are proposed to provide a comprehensive understanding of the present application. However, it is obvious to those skilled in the art that the present application can be implemented without some of these specific details. The following description of the embodiments is only for providing a better understanding of the present application by showing examples of the present application.

It should be noted that, in the present application, relational terms such as first and second, etc. are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such process, method, article or device. In the absence of further restrictions, the elements defined by the sentence “include . . . ” do not exclude the existence of other identical elements in the process, method, article or device including the elements.

The embodiments of the present application provide a pixel arrangement structure, a mask assembly and a display panel. Various embodiments of the display panel and the electronic apparatus will be described below in conjunction with the drawings.

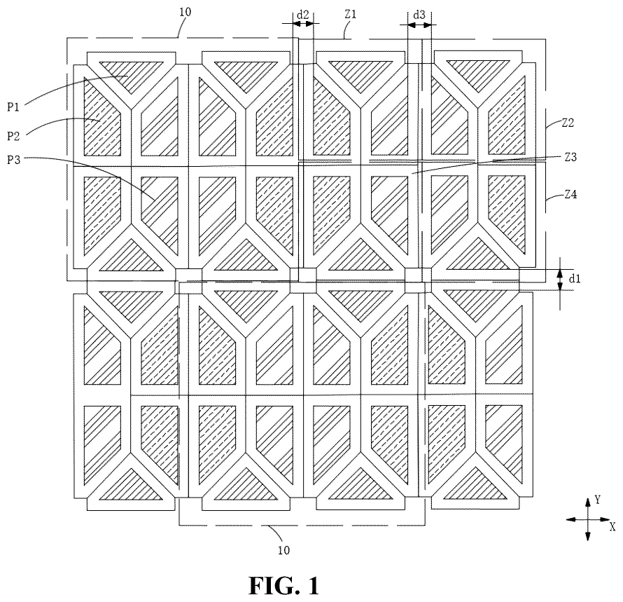

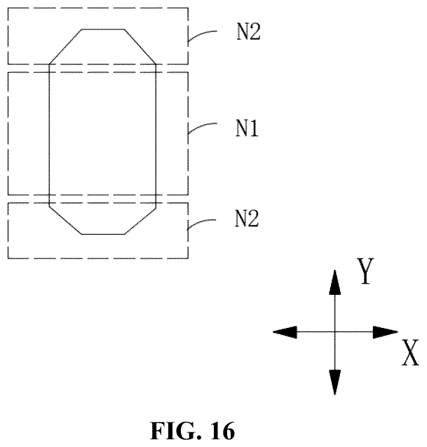

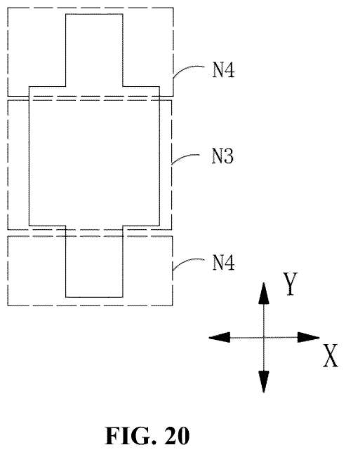

In order to better understand the present application, the pixel arrangement structure, the mask assembly and the display panel are described in detail below according to the embodiments of the present application in conjunction with FIG. 1 to FIG. 20.

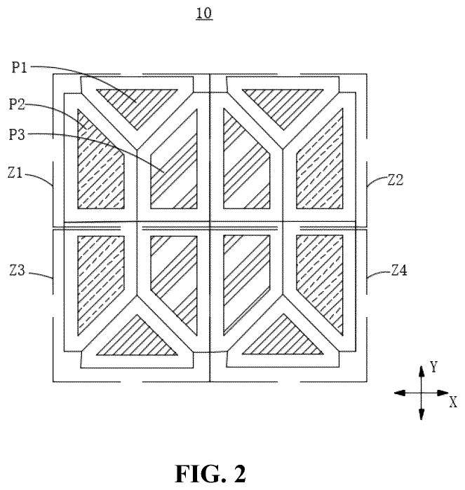

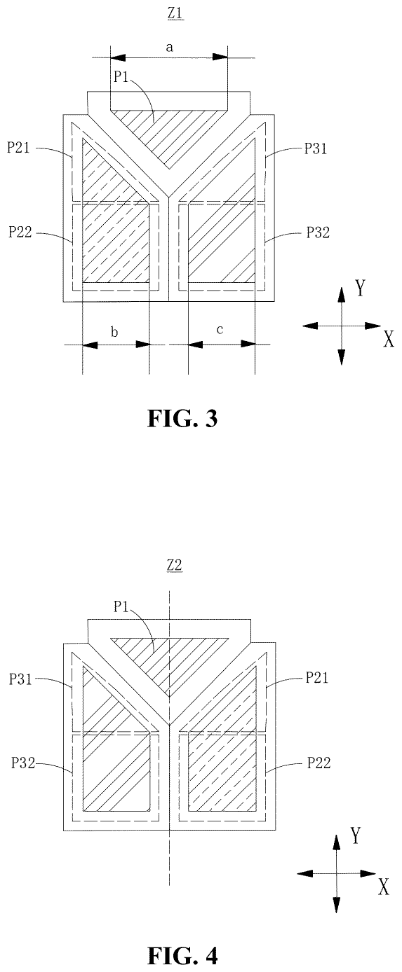

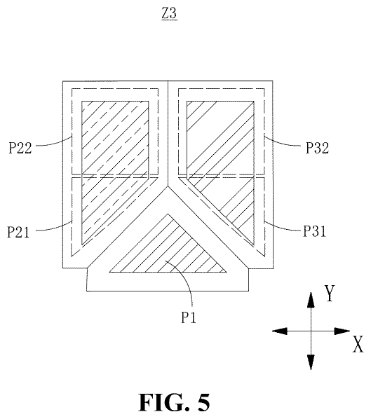

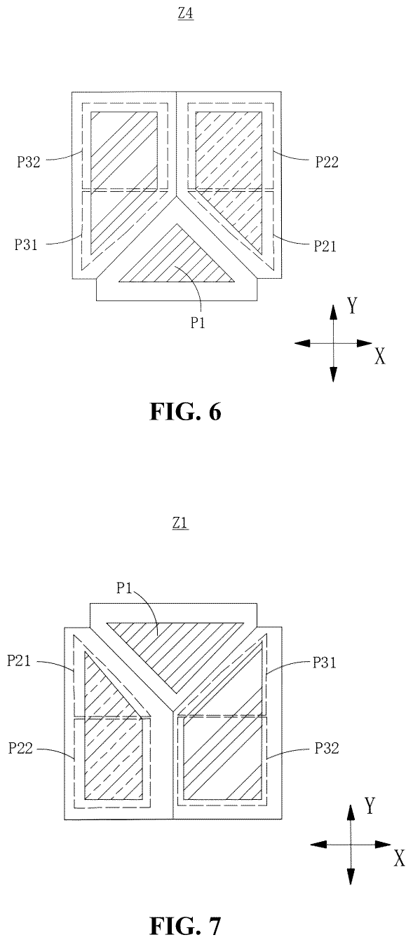

Referring to FIG. 1 to FIG. 6, FIG. 1 is a schematic diagram of a pixel arrangement structure provided by an embodiment of the present application; FIG. 2 is a schematic diagram of a pixel repeating unit provided by an embodiment of the present application; FIG. 3 is a schematic diagram of a first pixel group Z1 provided by an embodiment of the present application; FIG. 4 is a schematic diagram of a second pixel group Z2 provided by an embodiment of the present application; FIG. 5 is a schematic diagram of a third pixel group Z3 provided by an embodiment of the present application; and FIG. 6 is a schematic diagram of a fourth pixel group Z4 provided by an embodiment of the present application.

The embodiments of the present application provide a pixel arrangement structure, including a plurality of pixel repeating units, the pixel repeating units are repeatedly arranged along a first direction X and a second direction Y, and the first direction X and the second direction Y intersect; each of the pixel repeating units includes a first pixel group Z1, a second pixel group Z2, a third pixel group Z3, and a fourth pixel group Z4, wherein along the first direction X, the first pixel group Z1 and the second pixel group Z2 are arranged adjacently, and the first pixel group Z1 and the second pixel group Z2 are arranged in mirror symmetry in the second direction Y, and along the second direction Y, the third pixel group Z3 and the first pixel group Z1 are arranged adjacently, and the fourth pixel group Z4 and the second pixel group Z2 are arranged adjacently. The third pixel group Z3 and the first pixel group Z1 are arranged in mirror symmetry in the first direction X, and the fourth pixel group Z4 and the second pixel group Z2 are arranged in mirror symmetry in the first direction X; the first pixel group Z1 includes a first sub-pixel P1, a second sub-pixel P2 and a third sub-pixel P3; in the pixel repeating unit, the four third sub-pixels P3 corresponding to the first pixel group Z1, the second pixel group Z2, the third pixel group Z3 and the fourth pixel group Z4 are arranged adjacently; along the first direction X, the four second sub-pixels P2 included in two adjacent pixel repeating units are arranged adjacently.

The pixel arrangement structure provided in the embodiments of the present application includes a plurality of pixel repeating units. Along the first direction X, the first pixel group Z1 and the second pixel group Z2 in the pixel repeating unit are arranged adjacently, and the first pixel group Z1 and the second pixel group Z2 are arranged in mirror symmetry in the second direction Y, that is, the first pixel group Z1 and the second pixel group Z2 are arranged in mirror symmetry with respect to the symmetry axis extending along the second direction Y. Similarly, the third pixel group Z3 and the first pixel group Z1 are arranged in mirror symmetry in the first direction X, and the fourth pixel group Z4 and the second pixel group Z2 are arranged in mirror symmetry in the first direction X, which means that the third pixel group Z3 and the first pixel group Z1 are arranged in mirror symmetry with respect to the symmetry axis extending along the first direction X, and the fourth pixel group Z4 and the second pixel group Z2 are arranged in mirror symmetry with respect to the symmetry axis extending along the first direction X, so as to improve the overall symmetry of the pixel repeating unit and ensure the uniformity and regularity of light output. On the other hand, in the pixel repeating unit, the four third sub-pixels P3 corresponding to the first pixel group Z1, the second pixel group Z2, the third pixel group Z3 and the fourth pixel group Z4 are arranged adjacently, so that the four adjacent third sub-pixels P3 can be formed through the same mask opening, reducing the manufacturing cost. Similarly, along the first direction X, the four second sub-pixels P2 included in two adjacent pixel repeating units are arranged adjacently, and the four adjacent third sub-pixels P3 can also be formed through the same mask opening, effectively increasing the opening area of the evaporation mask, reducing the difficulty of manufacture process for the evaporation mask, and no gap is reserved when carrying out the evaporating deposition of adjacent second sub-pixels P2 or adjacent third sub-pixels P3, while ensuring the aperture ratio, high-resolution display can be achieved.

In this embodiment, the pixel repeating units are repeatedly arranged along the first direction X and the second direction Y, which means that the pixel repeating units are arranged in an array along the first direction X and the second direction Y to form a pixel arrangement structure.

Optionally, the first direction X and the second direction Y are perpendicular to each other.

It should be noted that, in the pixel repeating unit, the four third sub-pixels P3 corresponding to the first pixel group Z1, the second pixel group Z2, the third pixel group Z3 and the fourth pixel group Z4 are arranged adjacently, and the center lines of the corresponding four third sub-pixels P3 can form a quadrilateral, such as a rectangle, a trapezoid, a parallelogram, etc., which needs to be set according to the specific arrangement of the pixel repeating units.

Similarly, along the first direction X, the four second sub-pixels P2 included in two adjacent pixel repeating units are arranged adjacently, and the center lines of the corresponding four second sub-pixels P2 can form a quadrilateral, such as a rectangle, a trapezoid, a parallelogram, etc., which needs to be set according to the specific arrangement of the pixel repeating units.

The mirror symmetry in the present embodiment means that respective pixel groups are symmetrical with respect to a certain straight line, and one half thereof is exactly the same as the other half, but is in the opposite direction with the other half. This straight line is called the axis of symmetry, which divides the pixel repeating unit into multiple mirror parts.

Referring to FIG. 4, in some optional embodiments, the second sub-pixel P2 and the third sub-pixel P3 are arranged in mirror symmetry with respect to the midline of the first sub-pixel P1 along the second direction Y.

It should be noted that the first sub-pixel P1 in the present embodiment is an axisymmetric figure at least in the second direction Y, that is, the first sub-pixel P1 includes a midline extending along the second direction Y, and the first sub-pixel P1 is symmetrically arranged with respect to the midline, while the second sub-pixel P2 and the third sub-pixel P3 are arranged in mirror symmetry with respect to the midline of the first sub-pixel P1 extending along the second direction Y, and are disposed on both sides of the first sub-pixel P1 along the first direction X respectively, so as to further improve the symmetry of the first sub-pixels P1, the second sub-pixels P2 and the third sub-pixels P3 along the second direction Y in the first pixel group Z1, the second pixel group Z2, the third pixel group Z3 and the fourth pixel group Z4.

According to actual needs, the second sub-pixel P2 and the third sub-pixel P3 may not be arranged in mirror symmetry with respect to the midline of the first sub-pixel P1 along the second direction Y, that is, the shapes of the second sub-pixel P2 and the third sub-pixel P3 or the relative positions with the first sub-pixel P1 may be different, and can be selected according to actual needs without special restrictions.

Referring to FIG. 3 to FIG. 6, in some optional embodiments, the second sub-pixel P2 includes a first portion P21 and a second portion P22 connected to each other, and the third sub-pixel P3 includes a third portion P31 and a fourth portion P32 connected to each other; along the second direction Y, the first portion P21 and the third portion P31 are arranged on both sides of the first sub-pixel P1 respectively, and along the first direction X, the second portion P22 and the fourth portion P32 are arranged on one side of the first sub-pixel P1.

It can be understood that when the second sub-pixel P2 and the third sub-pixel P3 are arranged in mirror symmetry with respect to the midline of the first sub-pixel P1 extending along the second direction Y, the shapes of the corresponding first portion P21 and the third portion P31 are the same, and the distance between the first portion P21 and the first sub-pixel P1 along the first direction X is equal to the distance between the third portion P31 and the first sub-pixel P1 along the first direction X.

For example, as shown in FIG. 4, the first portion P21 and the third portion P31 are arranged on the left and right sides of the first sub-pixel P1 respectively, that is, the first portion P21 and the third portion P31 are arranged on both sides of the midline of the first sub-pixel P1 extending along the second direction Y respectively, so as to facilitate light mixing with the first sub-pixel P1.

In addition, along the first direction X, the second portion P22 and the fourth portion P32 are arranged on one side of the first sub-pixel P1. Due to the symmetry requirement, the second portion P22 and the fourth portion P32 are arranged on the same side of the first sub-pixel P1. The specific shapes of the first portion P21, the second portion P22, the third portion P31, and the fourth portion P32 are not particularly limited. Different shapes can be selected according to actual needs, such as regular shapes such as rectangles and triangles, or other irregular shapes.

Referring to FIG. 3 to FIG. 6, in some optional embodiments, the first sub-pixel P1, the first portion P21, and the third portion P31 are all triangular, and the long sides of the first portion P21 and the third portion P31 are arranged opposite to and parallel to the waists of the first sub-pixel P1 respectively.

In this embodiment, the two sides of the first sub-pixel P1 are arranged opposite to and parallel to the long sides of the first portion P21 and the third portion P31 respectively, so as to improve the regularity of the arrangement positions of the first sub-pixel P1, the first portion P21, and the third portion P31, and reduce the difficulty of manufacture.

It should be noted that the first portion P21 and the third portion P31 may be the same triangle, and correspondingly, the first sub-pixel P1 is an isosceles triangle, that is, the two equal waists of the first sub-pixel P1 are arranged corresponding to the long sides of the first portion P21 and the third portion P31 respectively.

Referring to FIG. 7, FIG. 7 is a schematic diagram of the first pixel group Z1 provided by another embodiment of the present application; or, the first portion P21 and the third portion P31 may be triangles with different side lengths, and correspondingly, the first sub-pixel P1 may have two unequal sides arranged opposite to the long sides of the first portion P21 and the third portion P31 respectively.

Optionally, the second portion P22 and the fourth portion P32 are both rectangular to reduce the difficulty of manufacture and facilitate the arrangement of opening of the mask.

Optionally, the second portion P22 and the first portion P21 form a trapezoid, that is, the second sub-pixel P2 is a trapezoid, which may be a right-angled trapezoid. Similarly, the third portion P31 and the fourth portion P32 form a trapezoid, that is, the third sub-pixel P3 may also be a trapezoid, which may be a right-angled trapezoid.

Optionally, the first portion P21 and the third portion P31 are both right triangles, and a right-angled side of the first portion P21 may be exactly connected to a side of the second portion P22 in the form of a rectangle, for example, a right-angled side of the first portion P21 may be exactly connected to a short side of the second portion P22 in the form of a rectangle, and the lengths of a right-angled side of the first portion P21 and the short side of the second portion P22 in the form of a rectangle are equal. A right-angled side of the third portion P31 may be exactly connected to a side of the fourth portion P32 in the form of a rectangle, and the lengths of the two connected sides are equal.

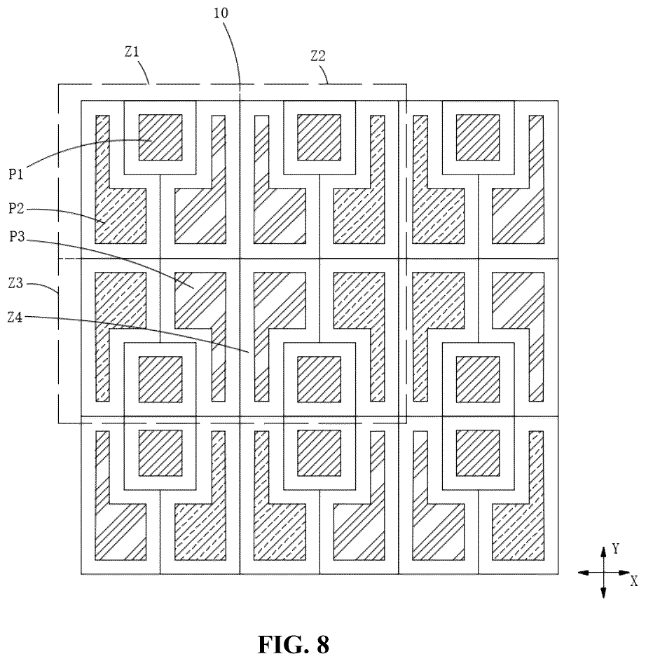

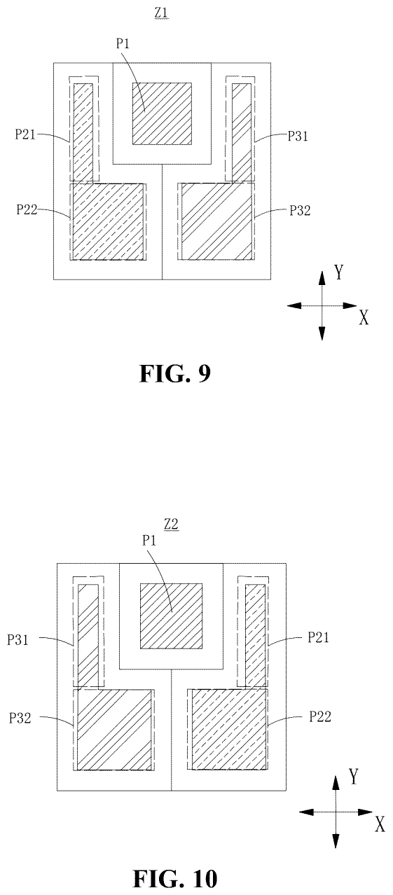

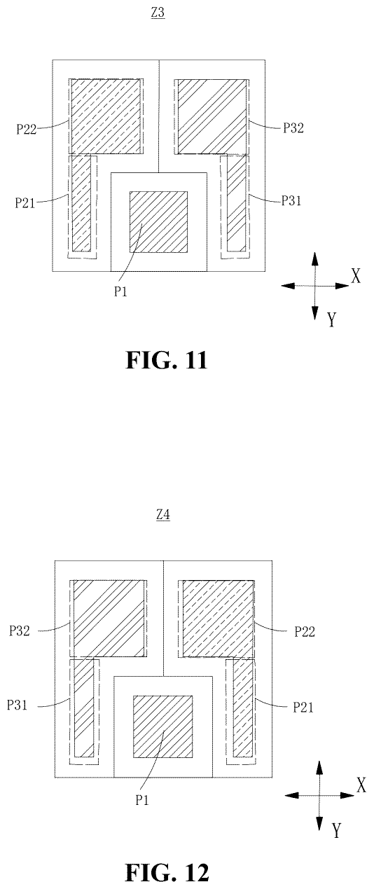

Referring to FIG. 8 to FIG. 12, FIG. 8 is a schematic diagram of a first pixel group Z1 provided by another embodiment of the present application; FIG. 9 is a schematic diagram of a pixel arrangement structure provided by another embodiment of the present application; FIG. 10 is a schematic diagram of a second pixel group Z2 provided by another embodiment of the present application; FIG. 11 is a schematic diagram of a third pixel group Z3 provided by another embodiment of the present application; and FIG. 12 is a schematic diagram of a fourth pixel group Z4 provided by another embodiment of the present application.

In some optional embodiments, the first sub-pixel P1 is rectangular; the first portion P21 and the third portion P31 are both rectangular, and along the second direction Y, the first portion P21 and the corresponding first sub-pixel P1 have sides that are opposite and parallel to each other, and the third portion P31 and the corresponding first sub-pixel P1 have sides that are opposite and parallel to each other.

It should be noted that the sides of the first portion P21 and the corresponding first sub-pixel P1 can all extend along the second direction Y, and the sides of the third portion P31 and the corresponding first sub-pixel P1 can all extend along the second direction Y, so as to facilitate the first portion P21 and the third portion P31 to be arranged in mirror symmetry with respect to the first sub-pixel P1 in the second direction Y.

Optionally, along the second direction Y, the length of the side of the first portion P21 opposite to the corresponding first sub-pixel P1 is greater than the length of the side of the corresponding first sub-pixel P1, so as to facilitate the connection between the first portion P21 and the second portion P22. Along the second direction Y, the length of the side of the third portion P31 opposite to the corresponding first sub-pixel P1 is greater than the length of the side of the corresponding first sub-pixel P1, so as to facilitate the connection between the third portion P31 and the fourth portion P32.

Referring to FIG. 9 to FIG. 12, in some optional embodiments, the second portion P22 and the fourth portion P32 are both rectangular, and along the first direction X, one side of the second portion P22 and the side of the corresponding first sub-pixel P1 are arranged opposite and parallel to each other, and one side of the fourth portion P32 and the side of the corresponding first sub-pixel P1 are arranged opposite and parallel to each other.

It should be noted that, along the first direction X, one side of the second portion P22 and the side of the corresponding first sub-pixel P1 are arranged opposite and parallel to each other, which means that one side of the second portion P22 extends along the first direction X to the position where the midline of the first sub-pixel P1 extending along the second direction Y is located, so that along the second direction Y, one side of the second portion P22 and the side of the corresponding first sub-pixel P1 partially overlap, that is, along the first direction X, one side of the second portion P22 and the side of the corresponding first sub-pixel P1 are arranged opposite to each other, and correspondingly, one side of the second portion P22 and the side of the corresponding first sub-pixel P1 both extend along the first direction X.

Similarly, one side of the fourth portion P32 and the side of the corresponding first sub-pixel P1 both extend along the first direction X.

Optionally, along the first direction X, the side of the first portion P21 away from the first sub-pixel P1 and the side of the second portion P22 away from the fourth portion P32 are connected to form a straight line. That is, the first portion P21 is arranged close to the edge of the second portion P22 away from the fourth portion P32 to avoid interference during manufacture.

Optionally, along the first direction X, the edge of the third portion P31 away from the first sub-pixel P1 and the edge of the fourth portion P32 away from the second portion P22 are connected to form a straight line. That is, the third portion P31 is arranged close to the edge of the fourth portion P32 away from the second portion P22.

Referring to FIG. 9 to FIG. 12, in some optional embodiments, the length of the second portion P22 along the first direction X is greater than the length of the first portion P21 along the first direction X, that is, the second portion P22 can be extended by a certain length with respect to the position where the midline of the first portion P21 extending to the first sub-pixel P1 along the second direction Y is located, so that the edge of the second portion P22 can be arranged opposite to the edge of the first sub-pixel P1 to improve the light mixing effect.

Optionally, the length of the fourth portion P32 along the first direction X is greater than the length of the third portion P31 along the first direction X, and the fourth portion P32 can be extended by a certain length with respect to the position where the midline of the third portion P31 extending to the first sub-pixel P1 along the second direction Y is located, so that the edge of the fourth portion P32 can be arranged opposite to the edge of the first sub-pixel P1 to improve the light mixing effect.

Referring to FIG. 1 or FIG. 8, in some optional embodiments, the pixel arrangement structure includes M columns and N rows of pixel repeating units. Along the second direction Y, the repeating units at the i+1-th row and the pixel repeating units at the i-th row are staggered by a predetermined distance, and the predetermined distance is equal to half of the total length of the pixel repeating units in the first direction X.

In this embodiment, the predetermined distance is equal to half of the total length of the pixel repeating units in the first direction X, and can be specifically equal to the length of any one of the first pixel group Z1, the second pixel group Z2, the third pixel group Z3 and the fourth pixel group Z4 along the first direction X, which improves the regularity of the pixel repeating unit arrangement and reduces the difficulty of manufacture.

The above arrangement can enable the first sub-pixel P1, the second sub-pixel P2 and the third sub-pixel P3 to be distributed more evenly in the entire pixel arrangement structure, avoiding the situation where there are too many same sub-pixels in the same direction. Therefore, when the pixel arrangement structure is applied to the display panel, the display effect can be improved as a whole and the difficulty of its manufacture process can be reduced.

For example, when i is equal to 1, along the second direction Y, the repeating units at the second row and the pixel repeating units at the first row are staggered by a predetermined distance, and the predetermined distance is equal to half of the total length of the pixel repeating units in the first direction X. When i is equal to 2, along the second direction Y, the repeating units at the third row and the pixel repeating units at the second row are staggered by a predetermined distance, and the predetermined distance is equal to half of the total length of the pixel repeating units in the first direction X. Correspondingly, the position and arrangement form of the pixel repeating units at the first row are the same as the position and arrangement form of pixel repeating units at the third row, that is, along the second direction Y, the arrangement forms of the repeating units at the i-th row and the pixel repeating units at the i+2-th row can be the same, which is convenient for manufacturing.

In some optional embodiments, the first sub-pixel P1 includes a red sub-pixel, the second sub-pixel P2 includes a blue sub-pixel, and the third sub-pixel P3 includes a green sub-pixel, which are specifically selected according to the material properties of the first sub-pixel P1, the second sub-pixel P2, and the third sub-pixel P3. The first sub-pixel P1, the second sub-pixel P2, and the third sub-pixel P3 can also use sub-pixels of other colors respectively, and are not limited to the above examples.

Optionally, the light-emitting area of the first sub-pixel P1 is smaller than the light-emitting area of the second sub-pixel P2 and the third sub-pixel P3 each.

Since the light-emitting attenuation of the blue sub-pixel is strong, when the light-emitting area of the blue sub-pixel is increased, the light-emitting consistency of the first sub-pixel P1, the second sub-pixel P2, and the third sub-pixel P3 can be guaranteed, the life color deviation of the screen is improved, thereby avoiding the display effect of the display panel being affected by the attenuation of the blue sub-pixel.

Optionally, the light-emitting areas of the second sub-pixel P2 and the third sub-pixel P3 may be the same, so as to realize that the second sub-pixel P2 and the third sub-pixel P3 are arranged in mirror symmetry with respect to the midline of the first sub-pixel P1 extending along the second direction Y. Alternatively, the light-emitting areas of the second sub-pixel P2 and the third sub-pixel P3 are different, and the corresponding shapes of the second sub-pixel P2 and the third sub-pixel P3 may be the same or different, and there is no special limitation, which may be determined by the performance of the materials of the second sub-pixel P2 and the third sub-pixel P3.

In some optional embodiments, the light-emitting area of the second sub-pixel P2 is greater than or equal to the light-emitting area of the first sub-pixel P1, and less than or equal to twice the light-emitting area of the first sub-pixel P1. Since the light-emitting efficiency of the blue sub-pixel material is relatively low when the second sub-pixel P2 adopts a blue sub-pixel, the light-emitting area of the second sub-pixel P2 may be increased to ensure the consistency of the light-emitting effects of the first sub-pixel P1 and the second sub-pixel P2.

And/or, the light-emitting area of the third sub-pixel P3 is greater than or equal to the light-emitting area of the first sub-pixel P1, and less than or equal to twice the light-emitting area of the first sub-pixel P1. By adjusting the sizes of light-emitting areas of the first sub-pixel P1, the second sub-pixel P2, and the third sub-pixel P3 to ensure the consistency of the light emissions of the first sub-pixel P1, the second sub-pixel P2, and the third sub-pixel P3, the display effect is improved.

Through research and experiments conducted by the inventor, it is found that compared with the pixel arrangement forms in the prior art, such as the π-type arrangement, the pixel arrangement structure provided by the embodiments of the present application has a higher pixel aperture ratio. In one example, in the first pixel group Z1 of the embodiments of the present application, the aperture ratio of the first sub-pixel P1 is 10.63%, the aperture ratio of the second sub-pixel P2 and the third sub-pixel P3 are both 20.12%, and the corresponding total aperture ratio is 50.9%. In the pixel unit of the π-type arrangement of the prior art, the aperture ratio of the first sub-pixel P1 is 8.31%, the aperture ratio of the second sub-pixel P2 is 15.98%, and the aperture ratio of the third sub-pixel P3 is both 15.92%, and the corresponding total aperture ratio is 40.21%. The total aperture ratio of the pixel arrangement structure provided by the embodiments of the present application is 26.6% greater than the total aperture ratio of the π-type arrangement of the prior art, thereby increasing the aperture ratio and improving the display effect.

The π-type arrangement refers to an arrangement in which the first sub-pixel P1 and the third sub-pixel P3 are arranged adjacently along the second direction Y, and along the first direction X, the first sub-pixel P1 and the third sub-pixel P3 each are arranged adjacently with the second sub-pixel P2.

Referring to FIG. 1, in some optional embodiments, along the second direction Y, the distance d1 between two adjacent first sub-pixels P1 is greater than or equal to 8 μm and less than or equal to 20 μm.

Taking into account the reasons such as the manufacture process error, along the second direction Y, the distance d1 between two adjacent first sub-pixels P1 should not be too small, which make the manufacturing difficult and the yield low, nor should it be too large, which reduce the aperture ratio and affect the display effect. Optionally, along the second direction Y, the distance d1 between two adjacent first sub-pixels P1 can be equal to any one of 8 μm, 10 μm, 12 μm, 14 μm, 16 μm, 18 μm, and 20 μm.

And/or, along the first direction X and/or the second direction Y, the distance d2 between two adjacent second sub-pixels P2 is greater than or equal to 8 μm and less than or equal to 20 μm. Optionally, along the first direction X, the distance d2 between two adjacent second sub-pixels P2 can be equal to any one of 8 μm, 10 μm, 12 μm, 14 μm, 16 μm, 18 μm, and 20 μm.

And/or, along the first direction X and/or the second direction Y, the distance d3 between two adjacent third sub-pixels P3 is greater than or equal to 8 μm and less than or equal to 20 μm. Optionally, along the first direction X, the distance d3 between two adjacent third sub-pixels P3 can be equal to any one of 8 μm, 10 μm, 12 μm, 14 μm, 16 μm, 18 μm, and 20 μm.

By limiting the distance between the first sub-pixel P1, second sub-pixel P2, and third sub-pixel P3 that are adjacent, the pixel density is increased and the light-emitting effect is improved while ensuring the manufacturing yield.

Referring to FIG. 3, in some optional embodiments, along the first direction X, the length a of the first sub-pixel P1 is less than the sum of the lengths of the second sub-pixel P2 and the third sub-pixel P3, that is, the sum of b and c in FIG. 3, so that along the second direction Y, the first portion P21 and the third portion P31 are arranged on both sides of the first sub-pixel P1 respectively, and the adjustment control of the light-emitting area of the first sub-pixel P1 is realized at the same time.

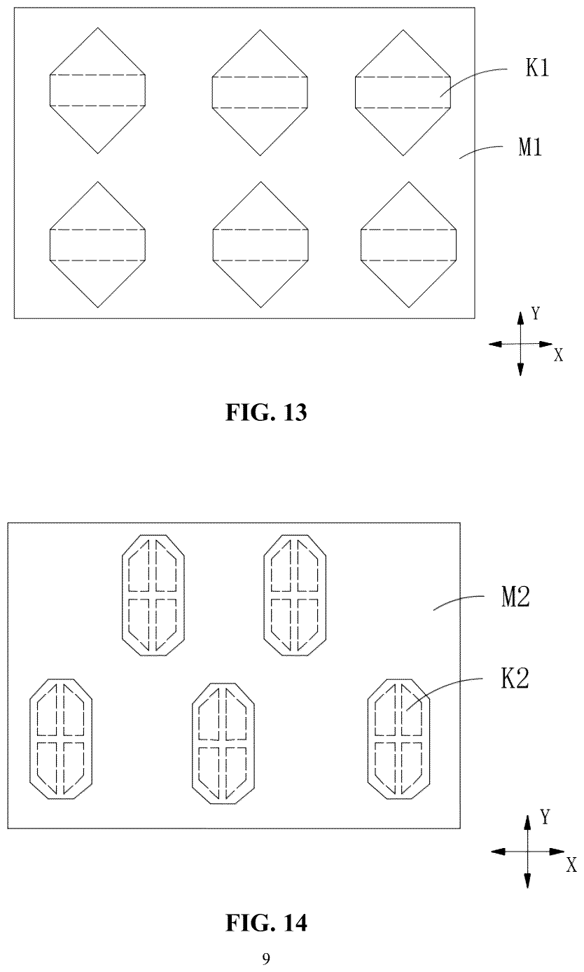

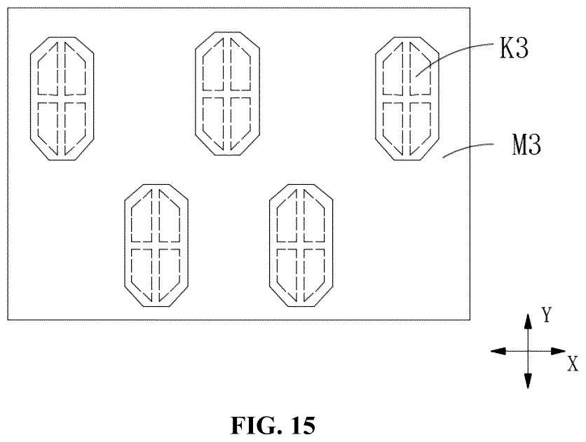

Referring to FIG. 13 to FIG. 15, FIG. 13 is a schematic diagram of a first sub-pixel mask M1 provided in an embodiment of the present application; FIG. 14 is a schematic diagram of a second sub-pixel mask M2 provided in an embodiment of the present application; FIG. 15 is a schematic diagram of a third sub-pixel mask M3 provided in an embodiment of the present application.

The embodiments of the present application further provide a mask assembly for manufacturing the pixel arrangement structure in any one of the above embodiments, the mask assembly includes: a first sub-pixel mask M1, having a first sub-pixel opening K1, the first sub-pixel opening K1 is configured to form two adjacent first sub-pixels P1 in two adjacent pixel repeating units along the second direction Y; and a second sub-pixel mask M2, having a second sub-pixel opening K2, the second sub-pixel opening K2 is configured to form four second sub-pixels P2 included in two adjacent pixel repeating units along the first direction X; a third sub-pixel mask M3, having a third sub-pixel opening K3, the third sub-pixel opening K3 is configured to form four adjacent third sub-pixel opening K3 sub-pixels in the pixel repeating unit.

The mask assembly provided by the embodiments of the present application includes a first sub-pixel mask M1, a second sub-pixel mask M2 and a third sub-pixel mask M3, which are configured for evaporating deposition of the first sub-pixel P1, the second sub-pixel P2 and the third sub-pixel P3 respectively. A first sub-pixel opening K1 can be configured to form two adjacent first sub-pixels P1 in two adjacent pixel repeating units along the second direction Y, so as to reduce the number of first sub-pixel openings K1 required to be arranged, and at the same time increase the opening area of the first sub-pixel opening K1, thereby reducing the difficulty of manufacture process for the evaporation mask. Similarly, a second sub-pixel opening K2 can form four second sub-pixels P2 included in two adjacent pixel repeating units along the first direction X, and a third sub-pixel opening K3 can form four adjacent third sub-pixels P3 in the pixel repeating unit, that is, four second sub-pixels P2 share one second sub-pixel opening K2, and four third sub-pixels P3 share one third sub-pixel opening K3, thereby effectively increasing the opening area of the evaporation mask, reducing the difficulty of manufacture process for the evaporation mask, and achieving high-resolution display while ensuring the aperture ratio.

Referring to FIG. 13, in some optional embodiments, the first sub-pixel openings K1 are hexagonal and arranged in an array along the first direction X and the second direction Y. Correspondingly, the two first sub-pixels P1 formed can be triangular, and the base sides of the two triangles are arranged oppositely to correspond to the hexagonal first sub-pixel opening K1. The first sub-pixel opening K1 can also be in other shapes, such as rectangular, circular or other polygonal, irregular shapes, etc., which need to be selected according to the shape of the first sub-pixel P1 to be formed, and there is no special limitation.

Referring to FIG. 14 to FIG. 16, optionally, the second sub-pixel opening K2 and the third sub-pixel opening K3 each include a first sub-portion and two second sub-portions arranged on both sides of the first sub-portion along the second direction Y. The first sub-portion is rectangular, the second sub-portion is trapezoidal, and the base side of the second sub-portion is connected to the first sub-portion.

In the present embodiment, the shapes of the second sub-pixel opening K2 and the third sub-pixel opening K3 can be the same to reduce costs. The four second sub-pixels P2 formed corresponding to the second sub-pixel opening K2 can be formed and divided by the two midlines of the second sub-pixel opening K2 along the first direction X and the second direction Y. The four third sub-pixels P3 formed corresponding to the third sub-pixel opening K3 can be formed and divided by the two midlines of the third sub-pixel opening K3 along the first direction X and the second direction Y.

The first portion P21 of the second sub-pixel P2 formed corresponding to the second sub-pixel opening K2 is triangular, the second portion P22 is rectangular, the third portion P31 of the third sub-pixel P3 formed corresponding to the third sub-pixel opening K3 is triangular, and the fourth portion P32 is rectangular.

Optionally, the second sub-portion is an isosceles trapezoid.

Referring to FIG. 14 to FIG. 15, optionally, the second sub-pixel openings K2 and the third sub-pixel openings K3 are arranged in an array along the first direction X and the second direction Y. Along the second direction Y, two adjacent second sub-pixel openings K2 and two adjacent third sub-pixel openings K3 are staggered in the first direction X to form the second sub-pixel P2 and the third sub-pixel opening K3 located in different pixel repeating units respectively.

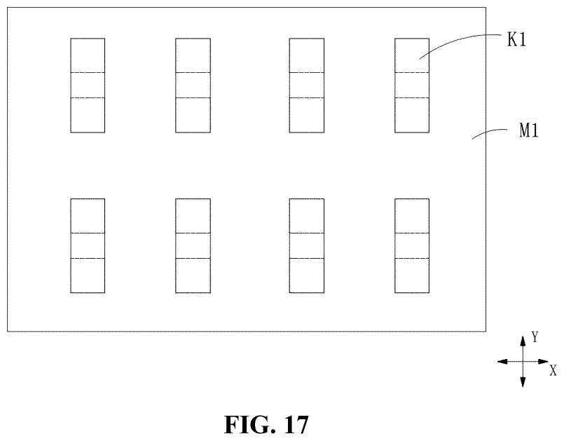

Referring to FIG. 17, in some optional embodiments, the first sub-pixel openings K1 are rectangular and arranged in an array along the first direction X and the second direction Y. Correspondingly, the first sub-pixel P1 may be rectangular.

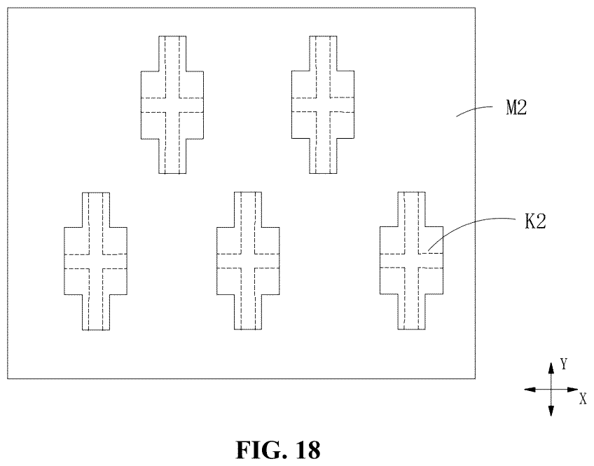

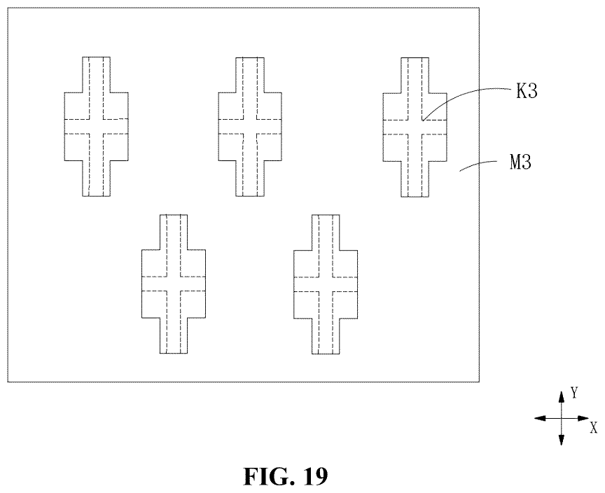

Referring to FIG. 18 to FIG. 20, optionally, the second sub-pixel opening K2 and the third sub-pixel opening K3 each include a third sub-portion and two fourth sub-portions arranged on both sides of the third sub-portion along the second direction Y. The third sub-portion is rectangular, the fourth sub-portion is rectangular, and the length of the side where the fourth sub-portion connects with the third sub-portion is less than the length of the side of the corresponding third sub-portion. The length of the side where the fourth sub-portion connects with the third sub-portion is less than the length of the side of the corresponding third sub-portion, so as to form a first portion P21 and a third portion P31 that are rectangular, and the second portion P22 and the fourth portion P32 are also rectangular.

Referring to FIG. 18 and FIG. 19, the second sub-pixel openings K2 and the third sub-pixel openings K3 are arranged in an array along the first direction X and the second direction Y. Along the second direction Y, two adjacent second sub-pixel openings K2 and two adjacent third sub-pixel openings K3 are staggered in the first direction X to form a second sub-pixel P2 and a third sub-pixel P3 located in different pixel repeating units respectively.

It can be understood that different pixel arrangement structures need to be manufactured using different masks.

The embodiments of the present application also provide a display panel, including the pixel arrangement structure in any one of the above embodiments.

The display panel provided by the embodiments of the present application has the technical effect of the technical solution of the pixel arrangement structure in any one of the above embodiments, and the structure and terminology that are the same or corresponding to the above embodiments are not repeated here.

The display panel provided by the embodiments of the present application can be an organic light-emitting diode (OLED) display panel, a quantum dot light-emitting diode (QLED) or a micro flat display panel (Micro-OLED or Micro-LED), etc.

The display panel provided in the embodiments of the present application can be applied to a mobile phone, or any electronic product with a display function, including but not limited to the following categories: televisions, laptops, desktop displays, tablet computers, digital cameras, smart bracelets, smart glasses, vehicle displays, medical equipment, industrial control equipment, touch interactive terminals, etc., which is not specifically limited in the embodiments of the present application.

The above is only a specific implementation of the present application. Those skilled in the art can clearly understand that for the convenience and simplicity of description, the specific working process of the system, module and unit described above can refer to the corresponding process in the aforementioned method embodiments, and will not be repeated here. It should be understood that the protection scope of the present application is not limited to this. Any technician familiar with the technical field can easily think of various equivalent modifications or replacements within the technical scope disclosed by the present application, and these modifications or replacements should be covered within the protection scope of the present application.

It should also be noted that the exemplary embodiments mentioned in the present application describe some methods or systems based on a series of steps or apparatuses. However, the present application is not limited to the order of the above steps, that is, the steps can be executed in the order mentioned in the embodiments, or they can be different from the order in the embodiments, or several steps can be executed simultaneously.

What is claimed is:

1. A pixel arrangement structure, comprising a plurality of pixel repeating units, the pixel repeating units being repeatedly arranged along a first direction and a second direction, and the first direction and the second direction intersecting with each other;
each of the pixel repeating units comprising a first pixel group, a second pixel group, a third pixel group and a fourth pixel group, along the first direction, the first pixel group and the second pixel group being arranged adjacently, and the first pixel group and the second pixel group being arranged in mirror symmetry in the second direction, along the second direction, the third pixel group and the first pixel group being arranged adjacently, the fourth pixel group and the second pixel group being arranged adjacently, the third pixel group and the first pixel group being arranged in mirror symmetry in the first direction, and the fourth pixel group and the second pixel group being arranged in mirror symmetry in the first direction;
the first pixel group comprising a first sub-pixel, a second sub-pixel and a third sub-pixel;
in the pixel repeating unit, the four third sub-pixels corresponding to the first pixel group, the second pixel group, the third pixel group and the fourth pixel group being arranged adjacently;
along the first direction, the four second sub-pixels comprised in the two adjacent pixel repeating units being arranged adjacently.

2. The pixel arrangement structure according to claim 1, wherein the second sub-pixel and the third sub-pixel are arranged in mirror symmetry with respect to a midline of the first sub-pixel along the second direction.

3. The pixel arrangement structure according to claim 1, wherein the second sub-pixel comprises a first portion and a second portion connected to each other, and the third sub-pixel comprises a third portion and a fourth portion connected to each other;
along the second direction, the first portion and the third portion are arranged on both sides of the first sub-pixel respectively, and along the first direction, the second portion and the fourth portion are arranged on a side of the first sub-pixel.

4. The pixel arrangement structure according to claim 3, wherein the first sub-pixel, the first portion and the third portion are all triangular, and long sides of the first portion and the third portion are arranged opposite and parallel to waists of the first sub-pixel respectively.

5. The pixel arrangement structure according to claim 3, wherein the first sub-pixel is an isosceles triangle.

6. The pixel arrangement structure according to claim 3, wherein the second portion and the fourth portion are both rectangular.

7. The pixel arrangement structure according to claim 3, wherein the first portion and the third portion are both right triangles.

8. The pixel arrangement structure according to claim 3, wherein the first sub-pixel is rectangular;
the first portion and the third portion are both rectangular, and along the second direction, the first portion and the corresponding first sub-pixel have sides that are arranged opposite and parallel to each other, and the third portion and the corresponding first sub-pixel have sides that are arranged opposite and parallel to each other.

9. The pixel arrangement structure according to claim 8, wherein the second portion and the fourth portion are both rectangular, and along the first direction, a side of the second portion and a side of the corresponding first sub-pixel are arranged opposite and parallel to each other, and a side of the fourth portion and a side of the corresponding first sub-pixel are arranged opposite and parallel to each other.

10. The pixel arrangement structure according to claim 3, wherein a length of the second portion along the first direction is greater than a length of the first portion along the first direction.

11. The pixel arrangement structure according to claim 1, wherein the pixel arrangement structure comprises M columns and N rows of the pixel repeating units, and along the second direction, the repeating units at an i+1-th row and the pixel repeating units at an i-th row are staggered by a predetermined distance, and the predetermined distance is equal to half of a total length of the pixel repeating units in the first direction.

12. The pixel arrangement structure according to claim 1, wherein the first sub-pixel comprises a red sub-pixel, the second sub-pixel comprises a blue sub-pixel, and the third sub-pixel comprises a green sub-pixel.

13. The pixel arrangement structure according to claim 1, wherein a light-emitting area of the first sub-pixel is smaller than a light-emitting area of the second sub-pixel and the third sub-pixel each.

14. The pixel arrangement structure according to claim 1, wherein a light-emitting area of the second sub-pixel is greater than or equal to a light-emitting area of the first sub-pixel, and less than or equal to twice the light-emitting area of the first sub-pixel;
and/or a light-emitting area of the third sub-pixel is greater than or equal to the light-emitting area of the first sub-pixel, and less than or equal to twice the light-emitting area of the first sub-pixel.

15. The pixel arrangement structure according to claim 1, wherein along the second direction, a distance between the two adjacent first sub-pixels is greater than or equal to 8 μm and less than or equal to 20 μm;
and/or, along the first direction and/or the second direction, a distance between the two adjacent second sub-pixels is greater than or equal to 8 μm and less than or equal to 20 μm;
and/or, along the first direction and/or the second direction, a distance between the two adjacent third sub-pixels is greater than or equal to 8 μm and less than or equal to 20 μm.

16. The pixel arrangement structure according to claim 1, wherein along the first direction, a length of the first sub-pixel is less than a sum of lengths of the second sub-pixel and the third sub-pixel.

17. A mask assembly for manufacturing a pixel arrangement structure comprising a plurality of pixel repeating units, the pixel repeating units being repeatedly arranged along a first direction and a second direction, and the first direction and the second direction intersecting with each other; each of the pixel repeating units comprising a first pixel group, a second pixel group, a third pixel group and a fourth pixel group, along the first direction, the first pixel group and the second pixel group being arranged adjacently, and the first pixel group and the second pixel group being arranged in mirror symmetry in the second direction, along the second direction, the third pixel group and the first pixel group being arranged adjacently, the fourth pixel group and the second pixel group being arranged adjacently, the third pixel group and the first pixel group being arranged in mirror symmetry in the first direction, and the fourth pixel group and the second pixel group being arranged in mirror symmetry in the first direction; the first pixel group comprising a first sub-pixel, a second sub-pixel and a third sub-pixel; in the pixel repeating unit, the four third sub-pixels corresponding to the first pixel group, the second pixel group, the third pixel group and the fourth pixel group being arranged adjacently; along the first direction, the four second sub-pixels comprised in the two adjacent pixel repeating units being arranged adjacently,
the mask assembly comprising:
a first sub-pixel mask having a first sub-pixel opening, the first sub-pixel opening being configured to form the two adjacent first sub-pixels in the two adjacent pixel repeating units along the second direction;
a second sub-pixel mask having a second sub-pixel opening, the second sub-pixel opening being configured to form the four second sub-pixels comprised in the two adjacent pixel repeating units along the first direction; and
a third sub-pixel mask having a third sub-pixel opening, the third sub-pixel opening being configured to form the four adjacent third sub-pixels in the pixel repeating unit.

18. The mask assembly according to claim 17, wherein the first sub-pixel openings are hexagonal and arranged in an array along the first direction and the second direction;
the second sub-pixel opening and the third sub-pixel opening each comprise a first sub-portion and two second sub-portions arranged on both sides of the first sub-portion along the second direction, the first sub-portion is rectangular, the second sub-portion is trapezoidal, and a base side of the second sub-portion is connected to the first sub-portion;
the second sub-pixel openings and the third sub-pixel openings are arranged in an array along the first direction and the second direction, and along the second direction, the two adjacent second sub-pixel openings and the two adjacent third sub-pixel openings are staggered in the first direction.

19. The mask assembly according to claim 17, wherein the first sub-pixel openings are rectangular and arranged in an array along the first direction and the second direction;
the second sub-pixel opening and the third sub-pixel opening each comprise a third sub-portion and two fourth sub-portions arranged on both sides of the third sub-portion along the second direction, the third sub-portion is rectangular, the fourth sub-portion is rectangular, and a length of a side connecting the fourth sub-portion and the third sub-portion is less than a length of a side of the corresponding third sub-portion;
the second sub-pixel openings and the third sub-pixel openings are arranged in an array along the first direction and the second direction, and along the second direction, the two adjacent second sub-pixel openings and the two adjacent third sub-pixel openings are staggered in the first direction.

20. A display panel, comprising a pixel arrangement structure comprising a plurality of pixel repeating units, the pixel repeating units being repeatedly arranged along a first direction and a second direction, and the first direction and the second direction intersecting with each other; each of the pixel repeating units comprising a first pixel group, a second pixel group, a third pixel group and a fourth pixel group, along the first direction, the first pixel group and the second pixel group being arranged adjacently, and the first pixel group and the second pixel group being arranged in mirror symmetry in the second direction, along the second direction, the third pixel group and the first pixel group being arranged adjacently, the fourth pixel group and the second pixel group being arranged adjacently, the third pixel group and the first pixel group being arranged in mirror symmetry in the first direction, and the fourth pixel group and the second pixel group being arranged in mirror symmetry in the first direction; the first pixel group comprising a first sub-pixel, a second sub-pixel and a third sub-pixel; in the pixel repeating unit, the four third sub-pixels corresponding to the first pixel group, the second pixel group, the third pixel group and the fourth pixel group being arranged adjacently; along the first direction, the four second sub-pixels comprised in the two adjacent pixel repeating units being arranged adjacently.
